(19) United States
(12) Patent Application Publication
(10) Pub. No.: US 2021/0048750 A1
(43) Pub. Date: Feb. 18, 2021

(54) ELECTRICALLY CONDUCTIVE MATERIAL

(71) Applicant: University of Exeter, Exeter, Devon (GB)

(72) Inventors: Monica Craciun, Exeter, Devon (GB); Saverio Russo, Exeter, Devon (GB)

(21) Appl. No.: 16/978,938

(22) PCT Filed: Mar. 7, 2019
(86) PCT No.: PCT/GB2019/050635

§ 371 Date: Sep. 8, 2020

(30) Foreign Application Priority Data
Mar. 9, 2018 (GB) 1803849.7

(51) Int. Cl. G03F 7/26; C01B 32/19; G03F 7/42; C01B 32/194; G03F 7/16; H01L 21/02

(52) U.S. Cl. CPC G03F 7/265; C01B 32/19; G03F 7/422; C01B 32/194; C01P 2006/40; H01L 21/02428; H01L 21/02527; H01L 21/02617; C01B 2204/22; G03F 7/161

(57) ABSTRACT

A method of producing a substrate provided with a shaped graphene material electrically conductive region is described, the method comprising applying a photoresist material to a substrate, shaping the photoresist material to cover at least part of the substrate that is not to be electrically conductive, depositing a graphene material onto the substrate over the shaped photoresist material, and subsequently removing the photoresist material. Also described are devices such as touch sensors and shaped light emitting devices manufactured using the method.

This invention relates to a method for use in the production of an electrically conductive material, and in particular to a method for use in the production of a textile or fibre material provided with a graphene material electrically conductive region of a desired shape. It also relates to a transfer method for use in transferring a graphene material to a substrate.

So-called smart textiles are a growth area, with potential applications in clothing, home fabrics, automotive textiles, medical diagnostics and health monitoring, and a number of other areas. Such applications require the provision of textiles or fibres having regions that are electrically conductive. For use over an extended period of time, the textiles or fibres are required to be able to flex repeatedly without significantly negatively impacting upon the ability of the conductive regions thereof to function.

It is thought that the use of graphene in such applications would be advantageous as graphene is well known to have good electrical conducting properties, and to be of good mechanical strength and flexibility.

One technique used in applying a pattern to a substrate is screen printing. This technique is used in applying conductive material patterns to circuit boards or other substrates by printing using conductive material inks. However, the resolution achievable using such techniques is fairly low, and complex technology and expensive inks are required to limit ink spreading. Also, post treatments may be required to remove solvents from the inks used.

WO2017/025697 describes a technique by which an electrically conductive track can be provided on a porous material such as a textile or fabric. The method involves applying a hydrophobic coating to the porous material and subsequently depositing a graphene material track or film onto the hydrophobic coating. The graphene material track or film is deposited using a printing technique such as inkjet printing, using a printing ink formulation incorporating the graphene material. By appropriate control over the printing technique, the graphene material track or film can be of a desired shape.

Other techniques involve shaping a graphene material element to a desired shape prior to depositing the element onto the fibre or textile.

It is thought that conductive regions formed using known techniques are adhered relatively poorly to the fibre and so repeated touching and/or bending may negatively impact upon the functioning of the electrically conductive regions thereof over time.

It is an object of the invention to provide an alternative technique by which a shaped graphene material electrically conductive region may be provided on a substrate such as a textile or fibre, the electrically conductive material being well adhered to the substrate.

According to the present invention there is provided a method of producing a substrate provided with a shaped graphene material electrically conductive region comprising applying a mask material to a substrate, shaping the mask material to cover at least part of the substrate that is not to be electrically conductive, depositing a graphene material onto the substrate over the shaped mask material, and subsequently removing the mask material. The mask material may comprise a photoresist material.

The use of such a method results in the production of a substrate upon which graphene material is deposited, the graphene material being of a desired shape and size, thus resulting in the substrate having an electrically conductive region of a desired shape and size formed thereon. The graphene material does not adhere to the parts of the substrate on which the photoresist material was present at the time of depositing the graphene material.

The substrate is conveniently of flexible form, and may comprise a fabric or textile material, or a textile fibre. By way of example, it may comprise a polypropylene fibre. The fibre may be in the form of a tape defining a substantially flat surface provided with the graphene material electrically conductive region. However, the invention is not restricted in this regard, and may be applied to rigid substrates.

The shaping of the photoresist material may be undertaken using a UV lithography technique. The removal of the photoresist material may be undertaken using acetone, for example.

The deposition of the graphene material may comprise an isopropyl alcohol assisted direct transfer process.

Where the substrate is of elongate, fibre or fibre like form then, depending upon the application in which the fibre is to be used, two or more such electrically conductive regions may be provided. By way of example, a touch sensor may be formed by provided two such conductive regions in close proximity to one another but electrically insulated from one another. In use, if a user places a finger to touch both of the conductive regions, the electrical resistance and/or capacitance between the regions will change, providing an indication that the sensor has been touched or activated.

Alternatively, a touch sensor may be formed using two such fibres which overlie one another, the fibres being electrically insulated from one another. In the event of the sensor being touched, the presence of the user's hand/finger touching the sensor may change the capacitance between the conductive regions of the fibres, the change in capacitance being used to provide an indication that the sensor has been touched or activated.

Another application in which the invention may be employed is in the production of a shaped light emitting device, the graphene material electrically conductive region forming a shaped electrode of such a device. By way of example, a layer of copper doped zinc sulphide may be positioned upon the shaped electrode, between the shaped electrode and a second electrode. In such an arrangement, the application of an AC voltage between the electrodes may cause the copper doped zinc sulphide layer to emit visible light.

The invention also relates to a textile or fibre material provided with a graphene material electrically conductive region of a desired shape using the above described method, and to products manufactured therefrom.

According to another aspect of the invention there is provided a method of transferring a graphene material to a substrate, wherein the graphene material is deposited using an isopropyl alcohol assisted direct transfer process. In the process, isopropyl alcohol is preferably deposited onto the substrate, the graphene material preferably comprising shear exfoliated graphene carried upon a porous membrane. The porous membrane is a filter membrane.

Evaporation of isopropyl alcohol may be promoted by heating to an elevated temperature to transfer the graphene material to the substrate. The elevated temperature may be in the region of 90° C.

The invention will further be described, by way of example with reference to the accompanying drawings, in which:

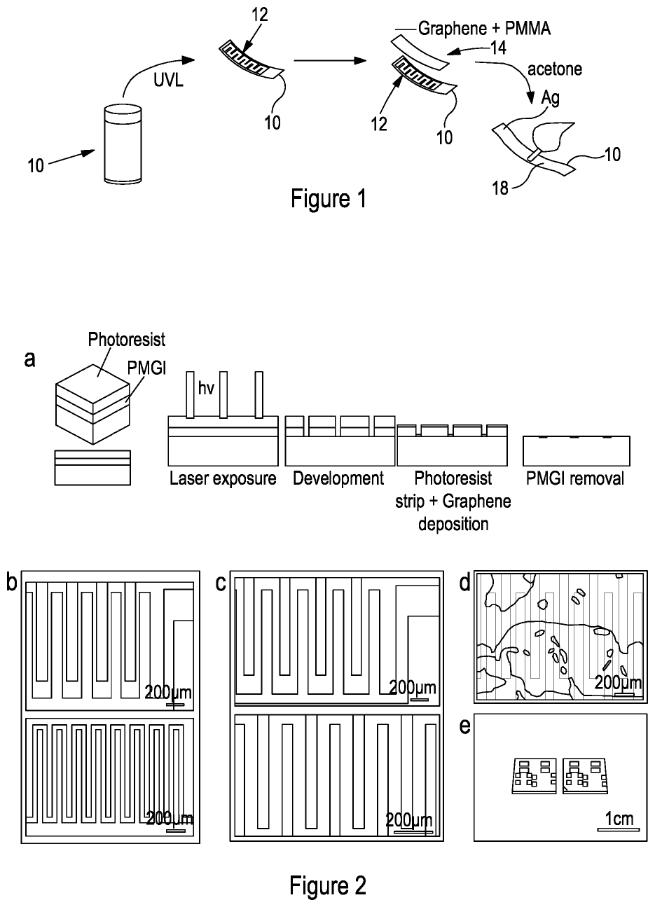

FIG. 1 is a diagrammatic illustration of steps of the method of an embodiment of the invention;

FIG. 2 is a diagrammatic representation of steps of another method; and

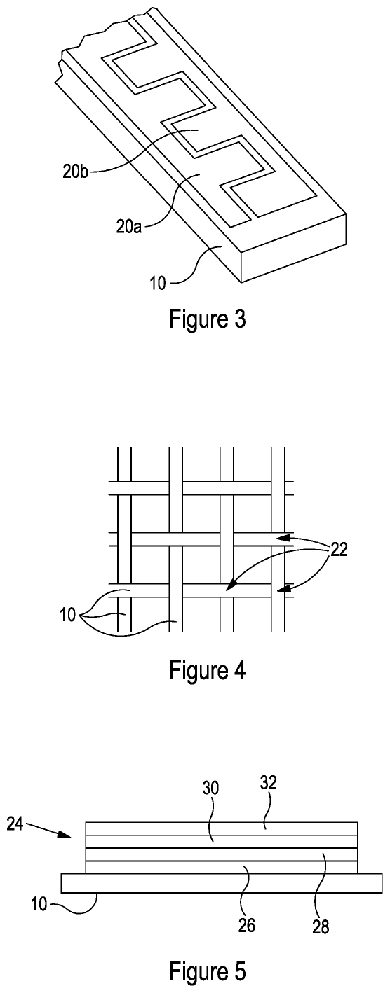

FIGS. 3 to 5 are diagrammatic views illustrating devices incorporating material produced using the methods.

Referring firstly to FIG. 1, a method for use in producing a textile fibre provided with a graphene material electrically conductive region is illustrated. In the arrangement illustrated, the textile fibre takes the form of a polypropylene tape 10, for example of width 2.4 mm and thickness 0.03 mm. It will be appreciated, however, that the invention is not restricted in this regard and may be applied to other substrate materials, for example to materials of different shapes and to materials of different dimensions.

The tape 10 has a layer 12 of a mask material, conveniently in the form of a photoresist material applied thereto. By way of example, the photoresist material may take the form of Microposit S1813 photoresist. The layer 12 of photoresist material is treated or patterned so as to be present only on those parts of the tape 10 which are not to be electrically conductive in the final product. The patterning of the layer 12 may be undertaken using a suitable patterning technique such as UV lithography. By way of example, a suitably shaped mask may be applied over the layer 12, and a developer used to result in the patterning of the layer 12 to take the desired form. Such UV lithography techniques are well known and will not be described herein in further detail.

A graphene material sheet 14 of a suitable shape and size is then deposited or transferred onto the tape 10 over the patterned layer 12. By way of example, chemical vapour deposition (CVD) techniques may be used to produce a graphene material layer supported upon a PMMA support layer, and the deposition or transfer of the graphene material sheet 14 onto the tape 10 may involve transferring the graphene material sheet 14 with the PMMA support layer in situ to the tape 10. Such transfer techniques are well known. The presence of the patterned photoresist layer 12 prevents adhesion of the graphene material sheet 14 to the parts of the tape 10 beneath the photoresist layer 12, the graphene material sheet 14 only adhering to those parts of the tape 10 not masked by the photoresist layer 12.

Graphene adhesion may be enhanced by subjecting the tape 10 to a mild oxygen plasma or to ultraviolet light in the presence of oxygen prior to the transfer of the graphene material 14 thereto. Once the graphene material has been transferred to the tape 10, a dry gun may be used to aid release of the graphene from the PMMA support layer and to promote adhesion to the tape 10.

Subsequently, the patterned photoresist layer 12 (and the PMMA support layer where present) are removed, for example by dissolving them in acetone. The removal of the patterned photoresist layer 12 also removes those parts of the graphene material sheet 14 not adhered to the tape 10. Accordingly, the removal of the photoresist layer 12 leaves the tape 10 with a patterned graphene material electrically conductive region 18 of a desired shape and size. The graphene material of the region 18 is well adhered to the tape 10. The shape and size of the region 18 accurately follows the shaping and dimensions of the photoresist material, which may be undertaken accurately using well known UV lithography techniques.

If desired, insulating material protective layers may be subsequently applied over the region 18.

Whilst the description hereinbefore makes reference to the use of a CVD produced graphene material sheet 14, it will be appreciated that the invention is not restricted in this regard and graphene material sheets 14 produced by other techniques may be used. By way of example, liquid exfoliation techniques may be used. The graphene material is preferably of single layer or few layer form.

An alternative transfer technique is illustrated diagrammatically in FIG. 2. In the arrangement of FIG. 2, shear exfoliation of graphite in water is undertaken, for example using sodium cholate as a surfactant. This is achieved by mixing graphite flakes and sodium cholate powder with deionised water, and using the high speed rotation of a shear mixer to cause shear exfoliation of the graphite flakes to form exfoliated graphene. The shear exfoliation results in the formation of a suspension of the shear exfoliated graphene in the water. The exfoliation process does not require the use of chemical treatments, the use of harsh conditions or require solvent exchanges to be undertaken. The process is thus relatively simple and lends itself to industrial exploitation. The graphite suspension formed in this manner is passed through a filter membrane to form a thin film of shear exfoliated graphene on the membrane.

To transfer the thin film of shear exfoliated graphene from the member to a substrate, an isopropyl alcohol assisted direct transfer technique is used. Isopropyl alcohol is positioned in the substrate on the part thereof onto which the graphene layer is required. The filter membrane carrying the thin film of graphene is then positioned onto the isopropyl alcohol with the thin film of graphene located on the side of the membrane facing towards the substrate. Evaporation of the isopropyl alcohol results in the graphene from the film being released from the membrane and driven towards the substrate. It is thought that this occurs as the evaporating isopropyl alcohol can only escape from between the substrate and the graphene film/filter membrane via the pores in the filter membrane. Whilst the evaporation of the isopropyl alcohol may occur at room temperature, and so the transfer process may be undertaken at room temperature, evaporation may be accelerated by heating the substrate to, for example, 90° C. Once the graphene film has been transferred in this manner, it will no longer be attached or adhered to the filter membrane, and so the filter membrane may be removed.

Subsequent dipping or washing in water can remove remaining sodium cholate from the deposited film.

It will be appreciated that if, prior to the application of the isopropyl alcohol to the substrate, an appropriately shaped and sized or patterned mask material layer is applied to the substrate, for example as described hereinbefore, the mask material can control to which areas of the substrate the graphene material is transferred, in use.

In greater detail, as shown in FIG. 2, the pattern is conveniently created using a double-layer resist consisting of PMGI and photoresist. Once patterned, for example using a conventional UV lithography technique and developed using TMAH-based developers (MF-319), the photoresist layer is removed with acetone and isopropyl alcohol. This leaves the patterned PMGI layer in position, which withstands acetone and isopropyl alcohol.

The graphene suspension is vacuum filtered onto a PTFE filter with a pore size of 40 μm as described hereinbefore. Once filtration has been completed, isopropyl alcohol is poured on top of the pre-patterned substrate, and the graphene/PTFE filter membrane is placed on top with the graphene facing the substrate/isopropyl alcohol, and subsequently placed on a hot-plate or furnace to increase the temperature up to 90° C. The isopropyl alcohol will evaporate and, by capillary forces, the graphene/PTFE will be dragged down towards the pre-patterned substrate, and some graphene flakes will be deposited onto the pre-patterned substrate by exfoliation of the graphene film from the PTFE filter. Whilst raising the temperature is convenient, this step can be undertaken at lower temperatures, or even room-temperature, if desired. The filter membrane is then removed, and the sample is dipped in a PMGI removal agent (for instance N-methyl-pyrrolidone (NMP) or developer TMAH developer (MF-319)), leaving just the patterned graphene material on the substrate.

This deposition method eliminates the need of an etching step, crucial when using solution-processed materials, enables low-temperature deposition, crucial when using polymeric flexible substrates, and theoretically can be used for any 2D material.

Accordingly, the methodology described hereinbefore with reference to FIG. 2 may be used in the application of a graphene material element of a desired shape and size to a substrate. The method may be undertaken quickly, transfer being undertaken in less than a minute, and may be used to transfer graphene to a range of materials, of flexible or rigid form, and of hydrophilic or hydrophobic form.

The manufacturing methods described hereinbefore may be used in the manufacture of fibres with electrically conductive regions for use in a range of application. By way of example, FIG. 3 illustrates a fibre including a region which, in use, serves as a touch sensor manufactured according to the method described hereinbefore. In the arrangement illustrated in FIG. 3, the method described hereinbefore is used to form two regions 20a, 20b of electrically conductive form, the regions 20a, 20b being slightly spaced apart from one another and electrically insulated from one another. Accordingly, in normal use the electrical resistance of the sensor is high. If a user were to touch the sensor in such a manner that his finger rests partly upon the region 20a and partly on the region 20b, the regions 20a, 20b are electrically shorted to one another, reducing the resistance of the sensor. The reduction in electrical resistance can be used to provide an indication that the sensor has been touched or activated. When the user removed his finger, the resistance returns to substantially its original level providing an indication that the user is no longer touching the sensor.

If insulating material layers are provided as mentioned hereinbefore, then rather than sense touching by detecting a change in resistance, a change in capacitance between the regions 20a, 20b may be used to indicate touching or activation of the sensor.

In the arrangement shown, the patterning or shaping of the electrically conductive regions 20a, 20b is such that they define a pair of interdigitated electrodes. Such an arrangement is advantageous in that it increases the likelihood of touching of the sensor being detected as there are a number of locations in which the user may touch the sensor and the touching action causing shorting of the regions 20a, 20b to one another, or a change in capacitance therebetween. It will be appreciated, however, that other shapes for the electrically conductive regions 20a, 20b are possible and, depending upon the application in which the sensor is to be user, may be preferred.

The invention allows shape features as small as 50 μm and at a pitch as small as 250 μm to be produced accurately.

FIG. 4 illustrates an alternative form of touch sensor. In the arrangement shown in FIG. 4, fibres manufactured using the method described hereinbefore are woven together to form a series of regions 22 at which the electrically conductive region of one of the fibres overlies the electrically conductive region of another of the fibres. The fibres are provided with an electrically insulating coating so that the electrically conductive regions are electrically insulated from one another. In the event that the user touches the sensor at the location at which the fibres overlie one another, the spacing of the fibres may change leading to a change in the capacitance between the conductive regions of the fibres. Furthermore, and importantly, the presence of the user's hand/finger touching the sensor will lead to a change in capacitance. The change in capacitance provides an indication that the sensor has been touched. By analysing the various fibre outputs, the location at which the sensor has been touched can be identified. Again, removal of the users finger/hand from the sensor returns the sensor capacitance to substantially its original level, providing an indication that the user is no longer touching the sensor. Sensing speeds in the region of 1.4 ms have been found to be possible with such a sensor.

FIG. 5 illustrates a shaped light emitting device 24. The device 24 comprises an electrically conductive graphene region 26 having substantially the same shape as the region required to emit light, in use, the region 26 having been formed on a substrate, for example in the form of a fibre using the method described hereinbefore. A layer 28 of a copper doped zinc sulphide emitter material is deposited over the region 26. A layer 30 of barium titanium oxide is deposited over the layer 28, and a silver paste electrode 32 is deposited over the layer 28. Excitation of the device 24 by applying an

AC voltage between the region 26 and the electrode 32 causes the layer 28 to emit light as a result of ionisation and recombination of electron-hole pairs. The shape of the region from which light is emitted is the same as that of the region 26, and so the method of the invention can be used to produce a shaped light source, conveniently upon a textile fibre or other flexible substrate.

Tests conducted upon the devices described hereinbefore have shown that repeated touching and bending does not significantly negatively impact upon their functionality. By way of example, texts involving bending or touching the device 500 times have not resulted in a significant loss of functionality. Accordingly, the method of the invention may be used to provide a range of electrical or electronic devices with a range of functionalities which are able to be used over an extended period of time in, for example, smart textiles and the like.

Whilst example substrate materials are mentioned hereinbefore, the invention is not restricted to the use of such materials. The substrate may be of flexible form or may be rigid. It may comprise, for example, PET, glass, paper, polypropylene or SiO₂/Si substrates.

Whilst the description hereinbefore is of specific example embodiments of the invention, it will be appreciated that a wide range of modifications and alterations may be made without departing from the scope of the invention as defined by the appended claims.

1. A method of producing a substrate provided with a shaped graphene material electrically conductive region comprising applying a mask material to a substrate, shaping the mask material to cover at least part of the substrate that is not to be electrically conductive, depositing a graphene material onto the substrate over the shaped mask material, and subsequently removing the mask material.

2. A method according to claim 1, wherein the substrate is of rigid form.

3. A method according to claim 1, wherein the substrate is of flexible form.

4. A method according to claim 3, wherein the substrate comprises one of a fabric material, a textile material, a textile fibre, a polypropylene fibre and a polypropylene tape.

5. (canceled)

6. A method according to claim 1, wherein the mask material comprises a photoresist material, and shaping of the photoresist material is undertaken using a UV lithography technique.

7. A method according to claim 1, wherein the conductive region includes features smaller in width than 100 μm.

8. A method according to claim 1, wherein the conductive region includes features having a width in the range of 50-100 μm.

9. A method according to claim 1, wherein the graphene material is deposited using an isopropyl alcohol assisted direct transfer process.

10. A method according to claim 9, wherein isopropyl alcohol is deposited onto a part of the substrate defined by the mask material, the graphene material comprising shear exfoliated graphene carried upon a porous membrane.

11. A method according to claim 10, wherein the porous membrane is a filter membrane.

12. A method according to claim 1 and used to produce a touch sensor.

13. A method according to claim 12, wherein the touch sensor comprises a substrate upon which two or more such electrically conductive regions are provided, the regions being electrically insulated from one another.

14. A method according to claim 12, wherein the touch sensor comprises two such substrates which overlie one another, the electrically conductive regions of the substrates being electrically insulated from one another, a change in the capacitance between the conductive regions providing an indication that the sensor has been touched or activated.

15. A method according to claim 1, and used to provide a shaped electrode.

16. A method according to claim 15, wherein the shaped electrode forms part of a shaped light emitting device.

17. A method according to claim 16, wherein the shaped light emitting device comprises a layer of copper doped zinc sulphide positioned upon the shaped electrode, between the shaped electrode and a second electrode.

18. A textile or fibre material provided with a graphene material electrically conductive region of a desired shape fabricated according to the method of claim 1.

19. A method of transferring a graphene material to a substrate, wherein the graphene material is deposited using an isopropyl alcohol assisted direct transfer process.

20. A method according to claim 19, wherein isopropyl alcohol is deposited onto the substrate, the graphene material comprising shear exfoliated graphene carried upon a porous membrane.

21. (canceled)

22. A method according to claim 20, wherein evaporation of isopropyl alcohol at an elevated temperature is used to transfer the graphene material to the substrate.

23. A method according to claim 22, wherein the elevated temperature is in the region of 90° C.
